(19) United States
(12) Patent Application Publication
(10) Pub. No.: US 2026/0302421 A1
(43) Pub. Date: Oct. 1, 2026

(54) BATTERY PACK OF VEHICLE

(71) Applicants: Hyundai Motor Company, Seoul (KR); Kia Corporation, Seoul (KR)

(72) Inventors: Yong Gyu LEE, Hwaseong-Si (KR); Sung Min HONG, Hwaseong-Si (KR)

(73) Assignees: Hyundai Motor Company, Seoul (KR); Kia Corporation, Seoul (KR)

(21) Appl. No.: 19/399,274

(22) Filed: Nov. 24, 2025

(30) Foreign Application Priority Data
Mar. 26, 2025 (KR) 10-2025-0038883

(51) Int. Cl. H01M 10/6568; H01M 10/42; H01M 10/613; H01M 10/6556; H01M 50/249; H01M 50/258

(52) U.S. Cl. CPC H01M 10/6568; H01M 10/425; H01M 10/613; H01M 10/6556; H01M 50/249; H01M 50/258

(57) ABSTRACT

A battery pack of a vehicle includes a plurality of battery modules, and a first cooling jacket including a flow path disposed therein through which a cooling medium flows. Each of the plurality of battery modules includes a battery, a power conversion module converting power from the battery, and a bus bar connecting the battery and the power conversion module. The bus bar may be disposed integrally with the first cooling jacket by being in contact therewith.

### CROSS-REFERENCE TO RELATED APPLICATION(S)

The present application claims benefit of priority to Korean Patent Application No. 10-2025-0038883 filed on Mar. 26, 2025, in the Korean Intellectual Property Office, the present disclosure of which is incorporated herein by reference in its entirety.

### BACKGROUND

### 1. Field

The present disclosure relates to a battery pack of a vehicle.

### 2. Description of Related Art

Typically, eco-friendly vehicles include a battery pack with multiple batteries and a power conversion module (for example, an inverter or converter). The battery pack and the power conversion module are connected via a busbar.

Recently, with the increased output of eco-friendly vehicles, there is a need to improve cooling performance by differentially cooling the battery and the power conversion module.

### BRIEF SUMMARY

According to various aspects of the present disclosure, the present disclosure provides a battery pack of a vehicle in which cooling performance of a busbar may be improved, thereby reducing a cross-sectional area of the busbar and thus reducing costs and weight of the busbar.

According to various aspects of the present disclosure, the present disclosure provides a battery pack of a vehicle in which cooling performance of a battery and a power conversion module may be improved.

According to various aspects of the present disclosure, the present disclosure provides a battery pack of a vehicle in which a cooling structure may be simplified and which may focus on cooling a battery during charging, thereby ensuring charging speed and stability while simultaneously reducing costs.

According to various aspects of the present disclosure, the present disclosure provides a battery pack of a vehicle in which cooling performance of a power conversion module and a battery may be differentially controlled.

According to various aspects of the present disclosure, a battery pack of a vehicle includes a plurality of battery modules; and a first cooling jacket including a flow path disposed therein through which a cooling medium flows. Each of the plurality of battery modules includes a battery; and a power conversion module converting power from the battery, and the power conversion module is in contact with a first surface of the first cooling jacket and the battery is in contact with a second surface of the first cooling jacket.

According to various aspects of the present disclosure, the flow path may be configured to differentially cool the power conversion module and the battery.

According to various aspects of the present disclosure, the flow path may be configured so that an area of a flow path adjacent to the power conversion module is smaller than an area of a flow path adjacent to the battery.

According to various aspects of the present disclosure, the flow path may include a plurality of first flow paths having a trapezoidal cross-sectional area.

According to various aspects of the present disclosure, the flow path may include a single second flow path having a quadrangular cross-sectional area, and a distance between the second flow path and the battery may be shorter than a distance between the second flow path and the power conversion module.

According to various aspects of the present disclosure, the flow path may include a single third flow path having a trapezoidal cross-sectional area.

According to various aspects of the present disclosure, thermal resistance of a heat transfer medium disposed between the first cooling jacket and the battery may be lower than thermal resistance of a heat transfer medium disposed between the first cooling jacket and the power conversion module.

According to various aspects of the present disclosure, the battery pack of a vehicle may further include a second cooling jacket that is in contact with lower surfaces of the plurality of battery modules and includes a flow path disposed therein through which a cooling medium flows.

According to various aspects of the present disclosure, the battery and the first cooling jacket, the first cooling jacket and the power conversion module, and the second cooling jacket and the plurality of battery modules may be in contact with each other via a heat transfer medium.

According to various aspects of the present disclosure, a flow rate of the cooling medium flowing through the flow path disposed within the second cooling jacket and a flow rate of the cooling medium flowing through the flow path disposed within the first cooling jacket may be independently adjusted.

According to various aspects of the present disclosure, the power conversion module may include at least one of a direct current(DC)/DC converter and a DC/AC inverter.

According to various aspects of the present disclosure, a battery pack of a vehicle includes a plurality of battery modules, a first cooling jacket including a flow path disposed therein through which a cooling medium flows, and a second cooling jacket including a flow path disposed therein through which a cooling medium flows. Each of the plurality of battery modules includes a battery; a power conversion module converting power from the battery; and a busbar connecting the battery and the power conversion module. The first cooling jacket includes an opening through which the busbar passes, the busbar is in contact with a side surface of the opening and an upper surface of the first cooling jacket, the power conversion module is in contact with one surface of the first cooling jacket, and the battery is in close contact with the other surface of the first cooling jacket, the plurality of battery modules are in contact with an upper surface of the second cooling jacket, and the flow path differentially cools the power conversion module and the battery.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a perspective view of a vehicle battery pack according to an exemplary embodiment of the present disclosure;

FIG. 2A is a top view of the battery pack illustrated in FIG. 1;

FIG. 2B is a cutaway view of the battery pack illustrated in FIG. 1, viewed from the side;

FIG. 2C is a diagram illustrating a flow path within a first cooling jacket according to an exemplary embodiment of the present disclosure;

FIG. 3A and FIG. 3B are diagrams illustrating a flow path within a first cooling jacket according to another exemplary embodiment of the present disclosure;

FIG. 4 is a diagram illustrating a first busbar disposed integrally with the first cooling jacket by with by being in contact therewith according to an exemplary embodiment of the present disclosure; and

FIG. 5 is a diagram illustrating an example circuit of a battery module according to an exemplary embodiment of the present disclosure.

### DETAILED DESCRIPTION

Hereinafter, detailed embodiments will be described with reference to the drawings. The following detailed description is provided to facilitate a comprehensive understanding of the methods, devices, and/or systems described herein. However, this is merely an example and the present disclosure is not limited thereto.

In describing embodiments, detailed descriptions of known technologies related to the present disclosure will be omitted if they are deemed to unnecessarily obscure the gist of the present disclosure. Furthermore, the terms described below are defined in consideration of their functions in the present disclosure and may vary depending on the intentions or practices of the user or operator, or the like. Therefore, their definitions should be based on the overall content of this specification. The terminology used in this detailed description is solely for the purpose of describing embodiments and should in no way be considered limiting. Unless expressly stated otherwise, singular forms include plural forms. In this description, expressions such as “including” or “having”, and the like are intended to indicate certain features, numbers, steps, operations, elements, or parts or combinations thereof, and should not be construed to exclude the presence or possibility of one or more other features, numbers, steps, operations, elements, or parts or combinations thereof, other than those described.

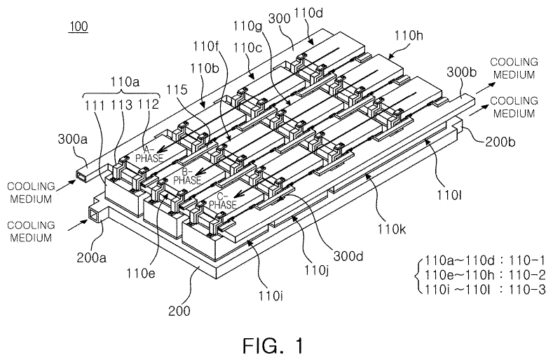

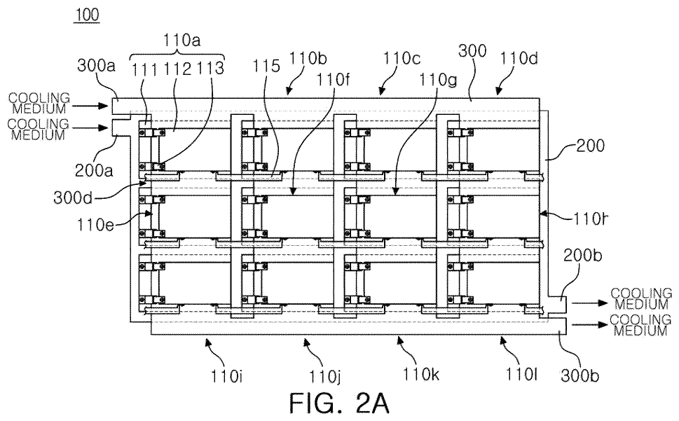

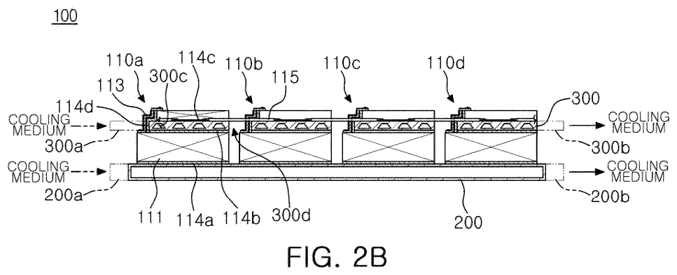

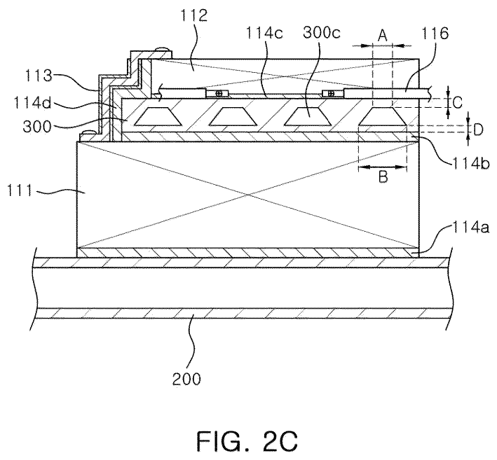

FIG. 1 is a perspective view of a vehicle battery pack according to an exemplary embodiment of the present disclosure. Furthermore, FIG. 2A is a top view of the battery pack illustrated in FIG. 1, FIG. 2B is a cutaway view of the battery pack illustrated in FIG. 1 viewed from the side, and FIG. 2C is a diagram illustrating a flow path within a first cooling jacket according to an exemplary embodiment of the present disclosure.

As illustrated in FIGS. 1, 2A, 2B and 2C, a battery pack 100 of a vehicle according to various exemplary embodiments of the present disclosure may include a plurality of battery modules 110a, 110b, 110c, 110d, 110e, 110f, 110g, 110h, 110i, 110j, 110k and 110l, a first cooling jacket 300, and a second cooling jacket 200. Although FIG. 1 illustrates 12 battery modules, it should be noted that this is to aid understanding of the present disclosure and is not limited to specific numerical values.

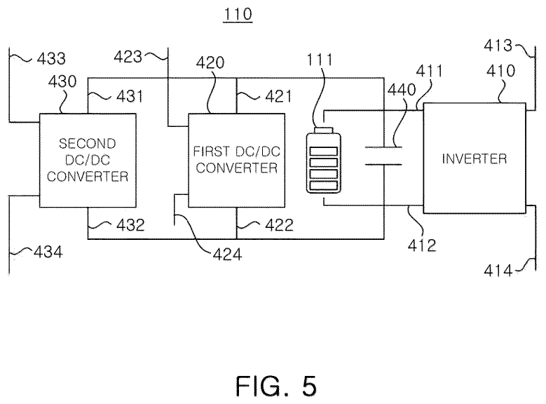

The plurality of battery modules 110a, 110b, 110c, 110d, 110e, 110f, 110g, 110h, 110i, 110j, 110k, and 110l may include three single-phase battery module systems 110-1, 110-2 and 110-3. Furthermore, the three single-phase battery module systems 110-1, 110-2 and 110-3 may include three-phase (A-phase, B-phase, C-phase) AC system output terminals configured by respectively connecting inverter output terminals (see 413 and 414 of FIG. 5, described below) in series via a first busbar 115. The three-phase (A-phase, B-phase, C-phase) AC system output terminals may output different AC voltages of the same magnitude and phase difference.

For example, the output terminals of a three-phase (A, B, C) AC system may output different AC voltages with a phase difference of 120 degrees. Therefore, the output terminals of a three-phase (A, B, C) AC system may output three-phase AC voltages and provide a driving voltage to a motor that utilizes the three-phase AC voltage as a driving voltage.

The first busbar 115 described above is disposed on the side of the battery module and may be in contact with the first cooling jacket 300. However, this is not necessarily limited to the present configuration, and the first busbar 115 may be disposed away from the first cooling jacket 300 so as not to come into contact with the first cooling jacket 300, and thus, cooling may be performed by air cooling.

The plurality of battery modules 110a, 110b, 110c, 110d, 110e, 110f, 110g, 110h, 110i, 110j, 110k and 110l respectively include the same structure. The following description focuses on the structure of one battery module 110a.

The battery module 110a may include a battery 111, a power conversion module 112 converting power from the battery 111, and a second busbar 113.

The second cooling jacket 200 adheres closely to the lower surfaces of the battery modules 110a, 110b, 110c, 110d, 110e, 110f, 110g, 110h, 110i, 110j, 110k and 110l, and may include a flow path disposed therein through which a cooling medium flows.

The cooling medium may be introduced through an inlet 200a, circulate across the entire surface of the second cooling jacket 200 along the flow path disposed within the jacket, and then discharge through an outlet 200b. While the cooling medium may be coolant, other cooling mediums may also be used.

Meanwhile, a battery 111 may be attached to one surface of the first cooling jacket 300, a power conversion module 112 may be attached to the other surface of the first cooling jacket 300, and a flow path 300c through which a cooling medium flows may be disposed within the first cooling jacket 300. Although the drawing illustrates the battery 111 being attached to the lower surface of the first cooling jacket 300 and the power conversion module 112 being attached to the upper surface of the first cooling jacket 300, it should be understood that, depending on an exemplary embodiment of the present disclosure, the battery 111 may be attached to the upper surface of the first cooling jacket 300 and the power conversion module 112 may be attached to the lower surface of the first cooling jacket 300. The cooling medium may be introduced through the inlet 300a, circulated across the entire surface of the first cooling jacket 300 along the flow path disposed therein, and then discharged through the outlet 300b.

The aforementioned flow path 300c may be disposed to differentially cool the power conversion module 112 and the battery 111, and the thermal resistance between the first cooling jacket 300 and the battery 111 may be smaller than the thermal resistance between the first cooling jacket 300 and the power conversion module 112. Alternatively, the aforementioned flow path 300c may be disposed so that the area of the flow path adjacent to the power conversion module 112 may be smaller than the area of the flow path adjacent to the battery 111.

To the present end, according to an exemplary embodiment of the present disclosure, as illustrated in FIG. 2C, the flow path 300c may include a plurality of first flow paths 300c including a trapezoidal cross-sectional area, and a widthwise length (A) of the flow path 300c adjacent to the power conversion module 112 may be formed to be smaller than a widthwise length (B) of the flow path adjacent to the battery 111. In the instant case, the distance (C) between the first flow path 300c and the power conversion module 112 may be configured to be shorter than or equal to the distance (D) between the first flow path 300c and the battery 111.

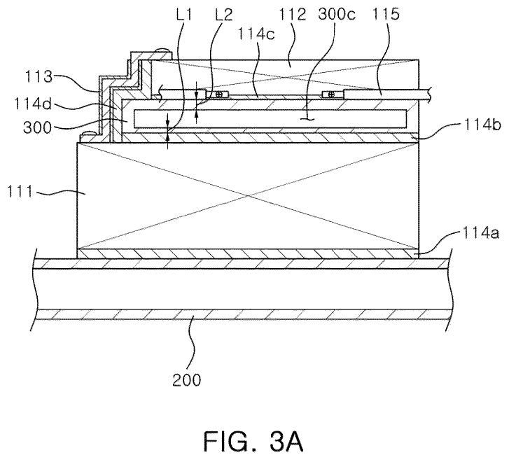

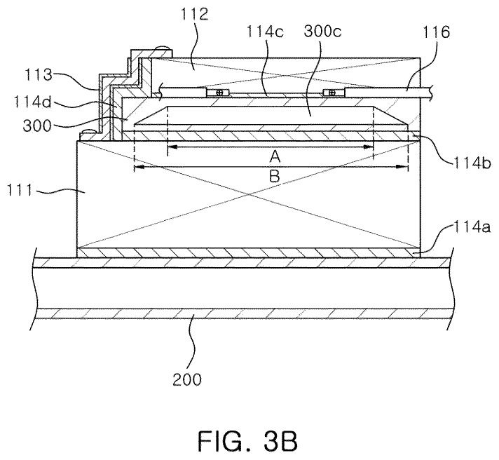

Alternatively, according to an exemplary embodiment of the present disclosure, as illustrated in FIG. 3A, the flow path may include a single second flow path 300c including a quadrangular cross-sectional area, but a distance L1 between the second flow path 300c and the battery 111 may be configured to be shorter than a distance L2 between the second flow path 300c and the power conversion module 112.

Alternatively, according to an exemplary embodiment of the present disclosure, as illustrated in FIG. 3B, the flow path may include a single third flow path 300c including a trapezoidal cross-sectional area. In the instant case, in the third flow path 300c, a widthwise length A of the flow path adjacent to the power conversion module 112 may be configured to be smaller than a widthwise length B of the flow path adjacent to the battery 111.

With the present configuration, the cooling performance of the power conversion module and the battery may be differentially controlled.

Alternatively, according to an exemplary embodiment of the present disclosure, as illustrated in FIGS. 2C, 3A and 3B, the thermal resistance of a heat transfer medium 114b disposed between the first cooling jacket 300 and the battery 111 may be smaller than the thermal resistance of a heat transfer medium 114c disposed between the first cooling jacket 300 and the power conversion module 112.

With the present configuration, the cooling performance of the power conversion module and the battery may be differentially controlled.

Meanwhile, the first cooling jacket 300 may include an opening 300d through which a second busbar 113 may pass. The second busbar 113 may be connected to the battery 111 and the power conversion module 112 via the opening 300d. The present second busbar 113 may be disposed integrally with the first cooling jacket 300.

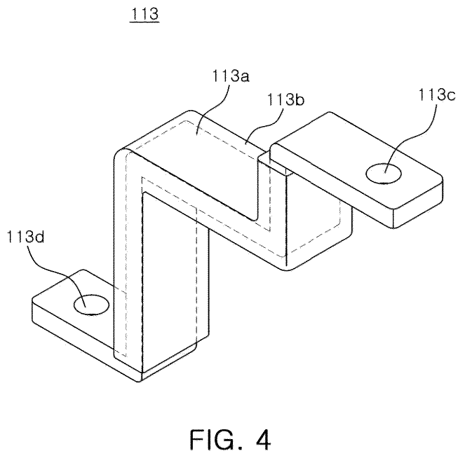

FIG. 4 is a drawing illustrating a second busbar disposed integrally with the first cooling jacket according to an exemplary embodiment of the present disclosure. The second busbar 113 may connect the battery 111 and the power conversion module 112.

As illustrated in FIG. 4, the second busbar 113 includes a conductor 113a, such as copper, and an insulating medium 113b (for example, insulating sheath, insulating paper, or the like) for insulating the conductor 113a. One side of the second busbar 113 may be screw-connected to the battery 111 through a groove 113d, and the other side may be screw-connected to the power conversion module 112 through a groove 113c.

According to an exemplary embodiment of the present disclosure, the second busbar 113 may be disposed integrally with the first cooling jacket 300 by being in contact therewith.

As illustrated in FIG. 2A, the second busbar 113 may be in contact with the side surface of the opening 300d, extending along the side surface of the opening 300d, and then bent to be in contact with the upper surface of the first cooling jacket 300. Additionally, the sides of the second busbar 113 and the opening 300d, as well as the sides of the second busbar 113 and the first cooling jacket 300, may be in contact with each other via a heat transfer medium 114d. The sides of the second busbar 113 and the power conversion module 112 may also be in contact with each other via the heat transfer medium 114d.

Referring again to FIG. 2B, the second cooling jacket 200 and the plurality of battery modules 110a, 110b, 110c and 110d, the battery 111 and the first cooling jacket 300, and the first cooling jacket 300 and the power conversion module 112 may be in contact with each other via heat transfer media 114a, 114b and 114c, respectively. The other multiple battery modules 110e to 110i may also be configured in the same manner.

The heat transfer media 114a, 114b, 114c and 114d may include thermal grease or a heat transfer pad.

Meanwhile, the flow rate of the cooling medium flowing through the flow path disposed within the second cooling jacket 200 and the flow rate of the cooling medium flowing through the flow path disposed within the first cooling jacket 300 may be independently controlled. To the present end, a valve or water pump may be disposed at the inlet 200a of the second cooling jacket 200 and the inlet 300a of the first cooling jacket 300, respectively, to independently control the flow rates of the cooling medium. This is merely an example of the present disclosure, and it is obvious that various implementations may be implemented according to the needs of those skilled in the art. Through the present configuration, the cooling performance of the power conversion module and the battery may be differentially controlled.

Meanwhile, the power conversion module 112 is a device for converting power of the battery 111 and may include at least one of a DC/DC converter and a direct current/alternating current (DC/AC) inverter.

FIG. 5 is a circuit diagram illustrating a battery module according to an exemplary embodiment of the present disclosure. The circuit illustrated in FIG. 5 is directed to aid understanding of the present disclosure, and it should be noted that the present disclosure is not limited to FIG. 5.

As illustrated in FIG. 5, a battery module 110 may include a battery 111, an inverter 410 connected to the battery 111, a first DC/DC converter 420, and a second DC/DC converter 430. Depending on an exemplary embodiment of the present disclosure, the battery module 110 may further include a common capacitor 440. The inverter 410, the first DC/DC converter 420, and the second DC/DC converter 430 may correspond to a power conversion module of the present disclosure.

The battery 111 may output a battery voltage and charge or discharge electrical energy. The battery voltage constitutes the base voltage of the battery module 110, providing the input voltage for the inverter 410, the first DC/DC converter 420, and the second DC/DC converter 430.

Furthermore, the battery 111 may have a lower voltage than that of the high-voltage battery packs used in electric vehicle drive systems of the related art. Therefore, the vehicle battery module 110 according to an exemplary embodiment of the present disclosure may utilize power conversion elements configured for operating at low voltages, thereby reducing manufacturing costs.

In the battery module 110 according to an exemplary embodiment of the present disclosure, voltages of various magnitudes and types depending on the series/parallel combination of the battery modules 110 may be output. Therefore, a single standard battery module 110 may be applied to various vehicle models, thereby reducing manufacturing costs.

For example, in the case in which the battery voltage is set to 100 V, a battery module system outputting 400 V may be formed by connecting four battery modules 110 in series, and a battery module system outputting 800 V may be formed by connecting eight battery modules 110 in series. Furthermore, if the battery voltage is set to 50 V, a battery module system outputting 400 V may be formed by connecting eight battery modules 110 in series, and a battery module system outputting 800 V may be formed by connecting sixteen battery modules 110 in series.

Furthermore, a single-phase battery module system may be formed by connecting battery modules 110 in series and using the inverter output to output high-voltage AC voltage. Alternatively, multiple single-phase battery module systems may be used to output three-phase AC voltage. Furthermore, a battery module system configured for carrying high current may be formed by connecting battery modules 110 in parallel.

The inverter 410 may convert battery voltage into AC module voltage and output the voltage. Furthermore, the inverter 410 may include input terminals 411 and 412 and output terminals 413 and 414. The inverter input terminals 411 and 412 are connected in parallel to the battery 111 to receive battery voltage, and the inverter output terminals 413 and 414 may output AC module voltage. In the present specification, the inverter output terminals 413 and 414 may also be referred to as AC module output terminals that output AC module voltage.

Furthermore, the first DC/DC converter 420 may convert the battery voltage into a first DC module voltage lower than the battery voltage and output the voltage. The first DC module voltage may be set as the driving voltage of a low-voltage load. For example, the low-voltage load may be electrical loads such as various lamps, radios, and infotainment systems in electric vehicles. The first DC module voltage may be set to a low-voltage load operating voltage, such as 12 V, 24 V, or 48 V. However, the voltage levels mentioned herein are merely examples and may be set to various voltage levels depending on the design.

The first DC/DC converter 420 may include input terminals 421 and 422 and output terminals 423 and 424. The input terminals 421 and 422 of the first DC/DC converter 420 may be connected in parallel to the battery 111 to receive the battery voltage, and the output terminals 423 and 424 of the first DC/DC converter 420 may output the first DC module voltage. In the present specification, the output terminals 423 and 424 of the first DC/DC converter 420 may also be referred to as the first DC module output terminal, which outputs the first DC module voltage.

Additionally, the output terminals 423 and 424 of the first DC/DC converter 420 may be directly connected to a low-voltage load to provide the first DC module voltage.

In an exemplary embodiment of the present disclosure, one end portion 424 of the output terminal of the first DC/DC converter 420 may be grounded, and the other end portion 423 thereof may be connected to the low-voltage load to output the first DC module voltage. In another exemplary embodiment of the present disclosure, both end portions of the output terminal of the first DC/DC converter 420 may be connected to both end portions of the low-voltage load to output the first DC module voltage.

The second DC/DC converter 430 may convert the battery voltage into a second DC module voltage and output the voltage. The second DC module voltage may be set to a value greater than the first DC module voltage output by the first DC/DC converter 420. The second DC module voltage may be less than or equal to the battery voltage, or may be greater than the battery voltage.

Furthermore, the second DC module voltage output from the second DC/DC converter 430 may be connected in series with the second DC module voltage output from another battery module 110 to provide power to a high-voltage load. In detail, the second DC module voltage output from the second DC/DC converter 430 does not provide power to a high-voltage load with a single output, but is connected in series with the second DC module voltage of another battery module 110 to provide power to the high-voltage load. Since the battery voltage included in the battery module 110 is configured as a low voltage, a plurality of battery modules 110 may be combined in series to provide a high voltage to provide voltage to a high-voltage load such as an air conditioning system. In detail, the output terminal of the second DC/DC converter 430 is connected in series with the output terminal of the second DC/DC converter 430 of another battery module to form a high voltage to provide power to the high-voltage load.

Additionally, the second DC/DC converter 430 may include input terminals 431 and 432 and output terminals 433 and 434. The input terminals 431 and 432 of the second DC/DC converter 430 may be connected in parallel with the battery 111 to receive the battery voltage, and the output terminals 433 and 434 of the second DC/DC converter 430 may output the second DC module voltage. In the present specification, the output terminals 433 and 434 of the second DC/DC converter 430 may also be referred to as the second DC module output terminal that outputs the second DC module voltage.

The output terminals 433 and 434 of the second DC/DC converter 430 may be connected in series with the output terminals of the second DC/DC converter 430 included in another battery module, or may be connected to a high-voltage load.

The battery 111 may be configured to be connected in parallel with the input terminals 411 and 412 of the inverter 410, the input terminals 421 and 422 of the first DC/DC converter 420, and the input terminals 431 and 432 of the second DC/DC converter 430.

The common capacitor 440 may be connected in parallel with the battery 111 and may be configured to be connected in parallel with the input terminals 411 and 412 of the inverter, the input terminals 421 and 422 of the first DC/DC converter, and the input terminals 431 and 432 of the second DC/DC converter.

According to the battery module 110 according to an exemplary embodiment of the present disclosure, a single common capacitor may be shared instead of separate capacitors for each inverter and converter element, thereby reducing volume. Furthermore, the application of low-voltage capacitors may reduce production costs.

As described above, according to an exemplary embodiment of the present disclosure, the cooling performance of the power conversion module and the battery may be differentially controlled by forming a flow path within the first cooling jacket so that the area of the flow path adjacent to the power conversion module is smaller than the area of the flow path adjacent to the battery, configuring the thermal resistance between the first cooling jacket and the battery to be smaller than the thermal resistance between the first cooling jacket and the power conversion module, or independently controlling the flow rate of the cooling medium flowing through the flow path disposed within the second cooling jacket and the flow rate of the cooling medium flowing through the flow path disposed within the first cooling jacket.

According to an exemplary embodiment of the present disclosure, a first cooling jacket is additionally disposed in a battery module including a battery, a power conversion module, and a busbar, and the busbar is integrally disposed with the first cooling jacket by being in contact therewith, thereby improving the cooling performance of the busbar and thus reducing the cross-sectional area of the busbar and reducing the cost and weight of the busbar.

Furthermore, according to an exemplary embodiment of the present disclosure, by gathering power conversion modules such as inverters and converters inside a battery pack and providing a cooling jacket for cooling the same inside the battery pack, the cooling structure may be simplified, and the cooling of the battery may be focused on during charging, thereby ensuring charging speed and stability while reducing costs.

As set forth above, according to an exemplary embodiment of the present disclosure, a flow path is disposed within a first cooling jacket so that the area of the flow path adjacent to the power conversion module is smaller than the area of the flow path adjacent to the battery, or the thermal resistance between the first cooling jacket and the battery is configured to be smaller than the thermal resistance between the first cooling jacket and the power conversion module, or the flow rate of a cooling medium flowing through a flow path disposed within a second cooling jacket and the flow rate of a cooling medium flowing through a flow path disposed within the first cooling jacket are independently adjustable, thereby enabling differential control of the cooling performance of the power conversion module and the battery.

In an exemplary embodiment of the present disclosure, a first cooling jacket is additionally disposed in a battery module including a battery, a power conversion module, and a busbar, and the busbar is integrally disposed in contact with the first cooling jacket, thereby improving the cooling performance of the busbar and thus reducing the cross-sectional area of the busbar and reducing the cost and weight of the busbar.

Furthermore, in an exemplary embodiment of the present disclosure, by gathering power conversion modules such as inverters and converters inside a battery pack and providing a cooling jacket for cooling the same inside the battery pack, the cooling structure may be simplified, and the cooling of the battery may be focused on during charging, thereby ensuring charging speed and stability while reducing costs.

While example embodiments have been illustrated and described above, it will be apparent to those skilled in the art that modifications and variations could be made without departing from the scope of the present disclosure as defined by the appended claims.

What is claimed is:

1. A battery pack of a vehicle, the battery pack comprising:
a plurality of battery modules; and
a first cooling jacket including a flow path disposed therein through which a cooling medium flows,
wherein each of the plurality of battery modules includes,
a battery; and
a power conversion module converting power from the battery, and
wherein the power conversion module is in contact with a first surface of the first cooling jacket and the battery is in contact with a second surface of the first cooling jacket.

2. The battery pack of claim 1, wherein the flow path differentially cools the power conversion module and the battery.

3. The battery pack of claim 1, wherein an area of the flow path adjacent to the power conversion module is smaller than an area of the flow path adjacent to the battery.

4. The battery pack of claim 1, wherein the flow path includes a plurality of first flow paths having a trapezoidal cross-sectional area.

5. The battery pack of claim 1,
wherein the flow path includes a single second flow path having a quadrangular cross-sectional area,
wherein a distance between the second flow path and the battery is shorter than a distance between the second flow path and the power conversion module.

6. The battery pack of claim 1, wherein the flow path includes a single third flow path having a trapezoidal cross-sectional area.

7. The battery pack of claim 1, wherein thermal resistance of a heat transfer medium disposed between the first cooling jacket and the battery is lower than thermal resistance of a heat transfer medium disposed between the first cooling jacket and the power conversion module.

8. The battery pack of claim 7, wherein the heat transfer medium includes a thermal grease or a heat transfer pad.

9. The battery pack of claim 1, further comprising a second cooling jacket in contact with lower surfaces of the plurality of battery modules and including a flow path disposed therein through which a cooling medium flows.

10. The battery pack of claim 8, wherein the battery and the first cooling jacket, the first cooling jacket and the power conversion module, and the second cooling jacket and the plurality of battery modules are in contact with each other through a heat transfer medium.

11. The battery pack of claim 9, wherein a flow rate of the cooling medium flowing through the flow path disposed within the second cooling jacket and a flow rate of the cooling medium flowing through the flow path disposed within the first cooling jacket are independently adjustable.

12. The battery pack of claim 1, wherein the power conversion module includes at least one of a DC/DC converter and a direct current/alternating current (DC/AC) inverter.

13. A battery pack of a vehicle, the battery pack comprising:
a plurality of battery modules, a first cooling jacket including a flow path disposed therein through which a cooling medium flows, and a second cooling jacket including a flow path disposed therein through which a cooling medium flows,
wherein each of the plurality of battery modules includes,
a battery;
a power conversion module converting power from the battery; and
a first busbar connecting the battery and the power conversion module,
wherein the first cooling jacket includes an opening through which the busbar passes,
wherein the busbar is in contact with a side surface of the opening and an upper surface of the first cooling jacket,
wherein the power conversion module is in contact with a first surface of the first cooling jacket, and the battery is in contact with a second surface of the first cooling jacket,
wherein the plurality of battery modules are in contact with an upper surface of the second cooling jacket, and
wherein the flow path differentially cools the power conversion module and the battery.

14. The battery pack of claim 13, further comprising:
a second busbar disposed on a side of the battery modules and in contact with the first cooling jacket.

15. The battery pack of claim 13, wherein the second cooling jacket is in contact with lower surfaces of the plurality of battery modules and includes a flow path disposed therein through which a cooling medium flows.

16. The battery pack of claim 13, wherein the battery and the first cooling jacket, the first cooling jacket and the power conversion module, and the second cooling jacket and the plurality of battery modules are in contact with each other through a heat transfer medium.

17. The battery pack of claim 16, wherein thermal resistance of the heat transfer medium disposed between the first cooling jacket and the battery is lower than thermal resistance of the heat transfer medium disposed between the first cooling jacket and the power conversion module.

18. The battery pack of claim 17, wherein the heat transfer medium includes a thermal grease or a heat transfer pad.
